(19) United States
(12) Patent Application Publication
(10) Pub. No.: US 2018/0061615 A1
(43) Pub. Date: Mar. 1, 2018

(54) PLASMA TREATMENT APPARATUS HAVING DUAL GAS DISTRIBUTION BAFFLE FOR UNIFORM GAS DISTRIBUTION

(71) Applicant: ACN Co., Ltd., Gyeonggi-do (KR)

(72) Inventors: Gyoodong Kim, Gyeonggi-do (KR); Woogon Shin, Gyeonggi-do (KR); Hyoseung Ahn, Gyeonggi-do (KR); Chiyoung Choi, Gyeonggi-do (KR)

(21) Appl. No.: 15/594,003

(22) Filed: May 12, 2017

Related U.S. Application Data
(60) Provisional application No. 62/381,315, filed on Aug. 30, 2016.

(30) Foreign Application Priority Data
Aug. 29, 2016 (KR) 10-2016-0110175

(51) Int. Cl. H01J 37/32; H01L 21/67; H01L 21/687

(52) U.S. Cl. CPC H01J 37/32449; H01J 37/32091; H01J 37/32724; H01L 21/67069; H01J 2237/335; H01L 21/68742; H01J 2237/202; H01J 2237/334; H01L 21/6704

(57) ABSTRACT

A plasma treatment apparatus includes a chamber configured to treat a substrate; a direct plasma generation region in the chamber into which process gas is introduced to directly induce plasma; a plasma inducing assembly configured to induce the plasma to the direct plasma generation region; a substrate treatment region in the chamber in which the plasma and vaporized gas introduced from the outside of the chamber are mixed with each other to form reactive species and the substrate is treated by the reactive species; a dual gas distributing baffle configured to provide the plasma to the substrate treatment region and distribute the vaporized gas to a center region and a peripheral region of the substrate treatment region; a plurality of through-holes formed through the dual gas distributing baffle so as to provide plasma to the substrate treating region; and a center buffer region configured to store the vaporized gas.

### CROSS-REFERENCE TO RELATED APPLICATION

This application claims the benefit of U.S. Provisional Application No. 62/381,315 filed on Aug. 30, 2016 and priority to Korean Patent Application No. 10-2016-0110175 filed on Aug. 29, 2016, with the Korean Intellectual Property Office, the disclosure of which is incorporated herein by reference.

### BACKGROUND

### Field of the Invention

The present invention relates to a plasma treatment apparatus having a dual gas distribution baffle for a uniform gas distribution, and more particularly, to a plasma treatment apparatus having a dual gas distribution baffle for a uniform gas distribution, capable of performing selective cleaning by generating a direct reaction to a thin film of a surface of a substrate to be treated directly using atoms or molecules having high reactivity.

### Description of the Related Art

A semiconductor, which is an active electronic element having functions such as storing, amplifying, switching, and the like, of electrical signals, is a core component inducing high-value-addition of a system industry and a service industry and leading digital information age based on high integration, high performance, and low power.

A semiconductor manufacturing process may be mainly divided into a pre-process (wafer machining process) and a post-process (assembling process and inspecting process), and a percentage occupied by a pre-process equipment market is about 75%. Among them, the sum of percentages occupied by a wet cleaning apparatus and dry etching called plasma etching is 22.6%, which forms the second largest market. In a semiconductor process, a scheme of manufacturing the respective components and circuits electrically connecting the respective components to each other as one pattern (circuit design diagram) and drawing the circuit pattern on thin films of several layers in the semiconductor is used. Here, a process of removing unnecessary portions on a substrate (wafer) on which the thin films are formed to expose the circuit pattern is an etching process. As the etching process, there are a dry etching process using plasma and a wet process using a cleaning solution.

The dry etching process is a physical and chemical etching process by vertical incidence particles through an ion flux using the plasma. Therefore, as a device design has become gradually small, a problem that damage is generated in the pattern depending on a process has occurred. The wet process, which is a technology that has been generally used for a long time, is a process of immersing the wafer in a container in which a cleaning solution is contained for a predetermined time or spraying the cleaning solution to the wafer while rotating the wafer at a predetermined speed to remove unnecessary portions on the surface of the wafer. However, the wet process has a disadvantage that a large amount of waste water is generated, such that it is difficult to adjust a cleaning amount and control a cleaning uniformity. In addition, the patterns after the cleaning have become larger or smaller than patterns intended on a design due to isotropic etching, such that it has been difficult to process fine patterns.

Recently, in accordance with an increase in a demand for an element having a faster processing speed and a high capacity memory, sizes of unit elements of a semiconductor chip have been continuously decreased. Therefore, gaps between the patterns formed on the surface of the wafer have become continuously narrow, and a thickness of a gate insulating layer of the element has become gradually thin. Therefore, problems that do not appear or are not important in an existing semiconductor process have been gradually revealed. Among them, a representative problem caused by the plasma is plasma damage. The plasma damage has an influence on characteristics and reliability of many elements including a transistor in all processes in which the surface of the wafer is exposed in accordance with the progress of miniaturization of a semiconductor element. Plasma damage to the thin film caused by the plasma mainly appears in the etching process. The plasma damage is a problem generated in the dry etching process or the wet process. An effort to solve the plasma damage has been demanded.

### SUMMARY

An object of the present invention is to provide a plasma treatment apparatus having a dual gas distribution baffle for a uniform gas distribution capable of performing cleaning by generating a direct reaction to a thin film of a surface of a substrate to be treated so as to prevent plasma damage.

Another object of the present invention is to provide a plasma treatment apparatus having a dual gas distribution baffle for a uniform gas distribution capable of uniformly treating a substrate by separately supplying water vapor to a center and an edge, especially by controlling amount and pressure of the gas supplied from a center so as to distribute and supply gas uniformly, in order to perform uniform plasma treatment.

According to an exemplary embodiment of the present invention, there is provided a plasma treating apparatus having a dual gas distribution baffle for a uniform gas distribution, comprising a chamber configured to treat a substrate to be treated; a direct plasma generation region in the chamber into which process gas is introduced to directly induce plasma; a plasma inducing assembly configured to induce the plasma to the direct plasma generation region; a substrate treatment region in the chamber in which the plasma introduced from the direct plasma generation region and vaporized gas introduced from the outside of the chamber are mixed with each other to form reactive species and the substrate to be treated is treated by the reactive species; a dual gas distributing baffle included between the direct plasma generation region and the substrate treatment region to provide the plasma to the substrate treatment region and distribute the vaporized gas to a center region and a peripheral region of the substrate treatment region; a plurality of through-holes formed through the dual gas distributing baffle so as to provide plasma generated in the direct plasma generation region to the substrate treating region; a center buffer region configured to be include in the dual gas distribution baffle and to store the vaporized gas supplied through the vaporized gas supplying path; one or more center vaporized gas discharging outlet configured to be included in the dual gas distribution baffle in order to spray the vaporized gas supplied to the center buffer region into the center region of the substrate treatment region; and one or more edge vaporized gas discharging outlet configured to spray the vaporized gas supplied through the vaporized gas supplying path formed in the dual gas distributing baffle into the peripheral region of the substrate treatment region.

According to an embodiment, the plasma inducing assembly may be a capacitively-coupled electrode assembly including a plurality of capacitively-coupled electrodes or a radio frequency antenna.

According to an embodiment, the plasma inducing assembly may include a center plasma inducing assembly configured to induce the plasma to a center region of the direct plasma generation region; and an edge plasma inducing assembly configured to induce the plasma to a peripheral region of the direct plasma generation region.

According to an embodiment, the dual gas distributing baffle may include a heat wire.

According to an embodiment, the vaporized gas may be vaporized H₂O.

According to an embodiment, the plasma apparatus may include one or mere gas inlets to supply the process gas into the chamber.

According to an embodiment, the plasma treating apparatus may include a diffuser plate installed to face the gas inlet through which the process gas is introduced to diffuse the process gas in the direct plasma generation region.

According to an embodiment, the center buffer region may include one or more buffer pillars in the center buffer region so that the vaporized gas supplied to the center buffer region is rotated and moved.

According to an embodiment, the dual gas distribution baffle may include a first center buffer region configured to store vaporized gas supplied through the vaporized gas supplying path; a first center vaporized gas discharging outlet configured to discharge the vaporized gas from the first center buffer region and to be formed therethrough; a second center buffer region configured to store the vaporized gas supplied through the first center vaporized gas discharging outlet; and a second center vaporized gas discharging outlet configured to spray the vaporized gas from the second center buffer region to the substrate treating region.

According to an embodiment, the first and second center buffer regions may include one or more buffer pillars through which the vaporized gas is rotated and moved.

According to a plasma treatment apparatus having a dual gas distribution baffle for a uniform gas distribution, it may be possible to treat a substrate to be processed

### BRIEF DESCRIPTION OF DRAWINGS

FIG. 1 is a view illustrating a plasma treating apparatus including a dual gas distributing baffle according to a first exemplary embodiment of the present invention.

FIG. 2 is a view schematically illustrating a structure of a capacitively-coupled electrode assembly of FIG. 1.

FIG. 3 is a plan view illustrating the top of the dual gas distributing baffle.

FIG. 4 is a plan view illustrating the bottom of the dual gas distributing baffle.

FIG. 5 is a flowchart illustrating a substrate treating method using the plasma treating apparatus.

FIG. 6 is a view illustrating a cross section of a dual gas distributing baffle according to a first exemplary embodiment of the present invention.

FIG. 7 is a view illustrating a center buffer region of a dual gas distributing baffle.

FIG. 8 is a view illustrating an edge supply path of a dual gas distributing baffle.

FIG. 9 is a view illustrating a plasma treating apparatus including a dual gas distribution baffle according to a second embodiment of the present invention.

FIG. 10 is a view illustrating a configuration of a dual gas distribution baffle according to a second embodiment of the present invention.

FIG. 11 is a view illustrating a first center buffer illustrated in FIG. 9.

FIG. 12 is a view illustrating a second center buffer illustrated in FIG. 9.

FIG. 13 is a view illustrating a plasma treating apparatus including a diffuser plate.

FIG. 14 is a plan view illustrating the diffuser plate.

FIG. 15 is a graph illustrating a plasma uniformity depending on a gap of the diffuser plate.

FIG. 16 is a flow chart illustrating a plasma treating method using the plasma treating apparatus of FIG. 13.

FIGS. 17 and 18 are views illustrating inductively-coupled plasma type plasma treating apparatuses.

FIGS. 19 and 20 are views illustrating plasma treating apparatuses having a plurality of gas inlets.

FIG. 21 is a view illustrating a plane of a hybrid chuck according to an exemplary embodiment of the present invention.

FIG. 22 is a view illustrating a cross section of the hybrid chuck of FIG. 21.

FIG. 23 is a flow chart of an operation method of the hybrid chuck.

### DETAILED DESCRIPTION

Exemplary embodiments of the present invention will be described with reference to the accompanying drawings in order to sufficiently understand the present invention. Exemplary embodiments of the present invention may be modified into several forms, and it is not to be interpreted that the scope of the present invention is limited to exemplary embodiments described in detail below. Exemplary embodiments are provided in order to completely explain the present invention to those skilled in the art. Therefore, shapes, or the like, of components in the accompanying drawings may be exaggerated for clarity. It is to be noted that the same components will be denoted by the same reference numerals throughout the accompanying drawings. A detailed description for the well-known functions and configurations that may unnecessarily make the gist of the present invention unclear will be omitted.

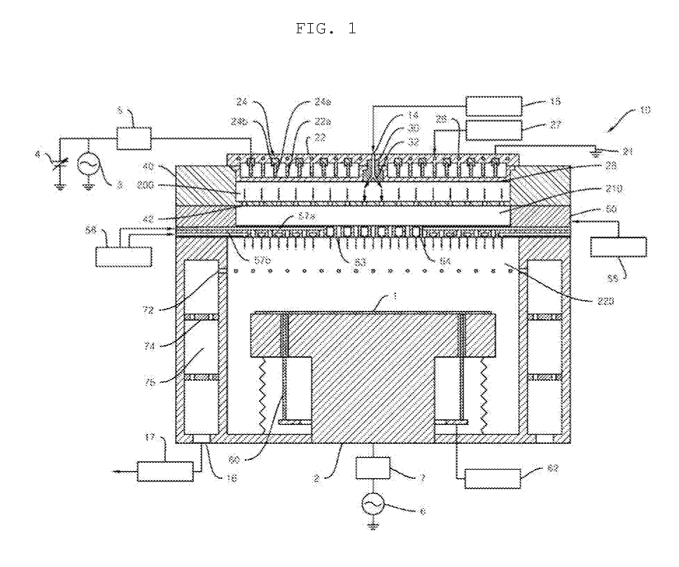

FIG. 1 is a view illustrating a plasma treating apparatus including a dual gas distributing baffle according to a first exemplary embodiment of the present invention.

Referring to FIG. 1, the plasma treating apparatus 10 according to the present invention is configured to include a chamber 12, a capacitively-coupled electrode assembly 20, a gas distributing baffle 40, a dual gas distributing baffle 50, and a power supply 3. The chamber 12 includes a substrate support 2 on which a substrate 1 to be treated is put. An upper portion of the chamber 12 is provided with a gas inlet 14 through which process gas for plasma treatment is supplied, and the process gas supplied from a process gas supply source 15 is supplied into the chamber 12 through the gas inlet 14. The gas inlet 14 is provided with a gas spraying head 30 having a plurality of gas spraying holes 32, and the process gas is supplied to a direct plasma generation region 200 through the gas spraying holes 32. The gas spraying head 30 is connected to the gas inlet 14 so that the process gas is sprayed downwardly of a dielectric window 28. A lower portion of the chamber 12 is provided with a gas outlet 16, which is connected to an exhaust pump 17. An exhaust region 75 in which an exhaust hole 72 is formed is formed at the lower portion of the chamber 12 while enclosing the substrate support 2. The exhaust hole 72 may have a form in which it is continuously opened or be formed of a plurality of through-holes. In addition, the exhaust region 75 is provided with one or more exhaust baffle 74 for uniformly exhausting exhaust gas.

The chamber 12 may be made of a metal material such as aluminum, stainless, or copper. Alternatively, the chamber 12 may also be made of a coated metal, for example, anodized aluminum or nickel-plated aluminum. Alternatively, the chamber 12 may also be made of a refractory metal. Alternatively, the chamber 12 may also be entirely or partially made of an electrical insulating material such as quartz or ceramic. As described above, the chamber 12 may be made of any material appropriate for performing an intended plasma process. The chamber 12 may have an appropriate structure depending on the substrate 1 to be treated and in order to uniformly generate plasma, for example, a circular structure or a rectangular structure, and may have a structure having any shape.

The substrate 1 to be treated may be substrates such as a wafer substrate, a glass substrate, a plastic substrate, and the like, for manufacturing various apparatuses such as a semiconductor apparatus, a display apparatus, a solar cell, and the like. The substrate support 2 may also be connected to a bias power supply 6. The substrate support 2 is provided with a lift pin 60 connected to a lift pin driving part 62 in order to raise or lower the substrate 1 to be treated while supporting the substrate 1 to be treated. The substrate support 2 may include a heater.

The capacitively-coupled electrode assembly 20 is disposed at an upper portion of the chamber 12 so as to form the ceiling of the chamber 12. The capacitively-coupled electrode assembly 20 includes a first electrode 22 connected to a ground 21 and second electrodes 24 connected to the power supply 3 to receive frequency power. The first electrode 22 forms the ceiling of the chamber 12 and is connected to the ground 21. The first electrode 22 is formed in one plate shape, and has a plurality of protrusion parts 22a formed at predetermined gaps and protruding inwardly of the chamber 12. The center of the first electrode 22 is provided with the gas inlet 14. The second electrodes 24 are provided between the protrusion parts 22a so as to be spaced apart from the first electrode 22 by a predetermined gap. Some of the second electrodes 24 are inserted into and mounted in the first electrode 22. Here, the second electrode 24 includes a power electrode 24a connected to the power supply 3 to receive radio frequency power and an insulating part 24b installed with the power electrode 24a and inserted into the first electrode 22. The insulating part 24a may also be formed to enclose the entire power electrode 24a. The first and second electrodes 22 and 24 generate directly capacitively-coupled plasma toward a plasma generation region. Although the capacitively-coupled electrode assembly 20 has been used as a component for inducing the plasma in the present invention, a radio frequency antenna may also be used as a component for generating inductively-coupled plasma. The power supply 3 is connected to the second electrodes 24 through an impedance matching device 5 to supply the radio frequency power to the second electrodes 24. A direct current (DC) power supply 4 may be selectively connected to the second electrodes 24.

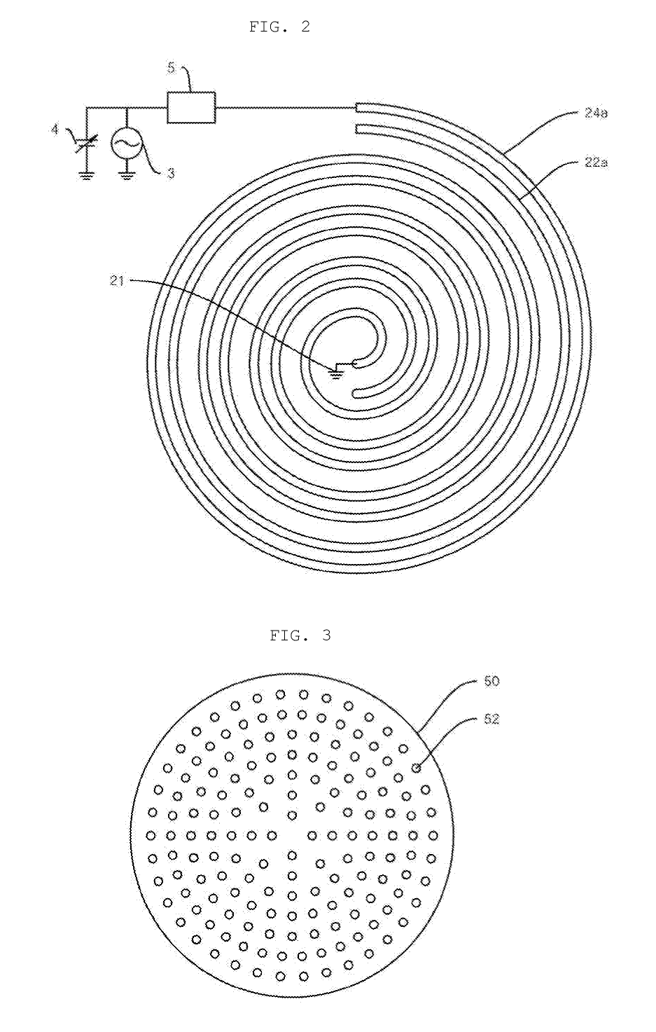

FIG. 2 is a view schematically illustrating a structure of a capacitively-coupled electrode assembly of FIG. 1.

Referring to FIG. 2, in the capacitively-coupled electrode assembly 20, the first electrode 22 connected to the ground 21 and the second electrode 24 connected to the power supply 3 are provided in a spiral structure. The protrusion part 22a of the first electrode 22 and the power electrode 24a of the second electrode 24 are spaced apart from each other by a predetermined gap to form a spiral structure. The power electrode 24a of the second electrode 24 and protrusion part 22a of the first electrode 22 face each other while maintaining a predetermined gap therebetween, thereby making it possible to generate uniform plasma. Here, the first and second electrodes 22 and 24 may be provided as parallel electrodes and be arranged in various structures. Although a case in which the first and second electrodes 22 and 24 have a rectangular shape has been illustrated in the present invention, a shape of the first and second electrodes 22 and 24 may be modified into various shapes such as a triangular shape, a circular shape, and the like.

The dielectric window 28 is provided between the capacitively-coupled electrode assembly 20 and the gas distributing baffle 40. The dielectric window 28 is robust to plasma damage and may be semi-permanently used. Therefore, the capacitively-coupled electrode assembly 20 is not exposed to the plasma by the dielectric window 28, such that damage to the first and second electrodes 22 and 24 is prevented.

Again referring to FIG. 1, the dual gas distributing baffle 50, which is a component for spraying vaporized gas to a substrate treatment region 230, is installed in the chamber so as to face the substrate support 2. The dual gas distributing baffle 50 includes a plurality of through-holes formed therein so as to penetrate therethrough and a plurality of center vaporized gas discharging outlets 53 and edge vaporized gas discharging outlets 54. The center vaporized gas discharging outlet 53 and the edge vaporized gas discharging outlet 54 are formed in a center supplying path 57a and an edge supplying path 57b provided in the dual gas distributing baffle 50 in order to move the vaporized gas, such that the vaporized gas supplied to the center and edge supplying paths 57a and 57b is sprayed to the outside of the dual gas distributing baffle 50. The center vaporized discharging outlets 53 and the edge vaporized gas discharging outlets 54 are formed in a lower surface of the dual gas distributing baffle 50 so that the vaporized gas is sprayed to the substrate treatment region 230. An amount of the vaporized gas supplied to a center region and a peripheral region of the substrate treatment region 230 is adjusted by the center vaporized discharging outlets 53 and the edge vaporized gas discharging outlets 54, thereby making it possible to uniformly form reactive species over the entire substrate treatment region 230. As a result, the substrate 1 to be treated may be uniformly treated by the uniformly formed reactive species. For example, the edge vaporized gas discharging outlets 54 may be restricted to sections Φ112˜Φ548.

The chamber 12 may be further provided with the gas distributing baffle 40 for uniformly distributing the plasma in the direct plasma generation region 200. The gas distributing baffle 40 is provided in the direct plasma generation regions 200 and 210, and uniformly distributes process gas dissociated by the plasma through a plurality of through-holes 42 formed therein so as to penetrate therethrough. The vaporized gas is supplied to the substrate treatment region 220 through the center and edge vaporized gas discharging outlets 53 and 54 of the dual gas distributing baffle 50, and the plasma is supplied to the substrate treatment region 220 through the through-holes 52 to form reactive species. The reactive species are adsorbed to a byproduct of the substrate 1 to be treated, such that it is removed in a heat treatment process. Cleaning in this scheme is called vapor phase etching.

In the vapor phase etching, which is an etching scheme having advantages of wet etching and dry etching, a direct reaction to a thin film of a surface of the substrate 1 to be treated is generated directly using atoms or molecules having high reactivity in a low temperature vacuum chamber to perform selective etching and cleaning. The vapor phase etching has advantages that selectivity is high, a control of a cleaning amount is easy, and plasma damage is not generated at all. In addition, the vapor phase etching has an advantage that a byproduct is not generally created and the byproduct may be sufficiently removed by a simpler method as compared with the wet etching even though the byproduct is created.

Vaporized water (H₂O) is used as the vaporized gas for forming the reactive species. NF₃, CF₄ (fluorine based), or the like, is used as main etchant gas for generating the plasma, and He, Ar, N₂ (inert gas), or the like, is used as carrier gas. It is preferable that each process pressure is several m torr to several hundred torr.

The gas distributing baffle 40 and the dual gas distributing baffle 50 may further include a heat wire as a heating means for adjusting a temperature. Here, the heating means may be formed in both of the gas distributing baffle 40 and the dual gas distributing baffle 50 or be formed in any one of the gas distributing baffle 40 and the dual gas distributing baffle 50. Particularly, the heat wire formed in the dual gas distributing baffle 50 receives power from a power supply 55 and continuously applies heat to the vaporized water (H₂O) passing through the center and edge supplying paths 57a and 57b, thereby allowing the vaporized water (H₂O) to arrive at the substrate 1 to be treated in a vaporized state without being liquefied. In addition, the dual gas distributing baffle 50 may be further provided with a sensor that may measure a temperature of the vaporized gas.

The plasma treating apparatus 10 may include a cooling channel 26 disposed in the first electrode 22 connected to the ground 21. The cooling channel 26 receives a coolant from a coolant supply source 27 to lower a temperature of the overheated first electrode 22, thereby making it possible to maintain the first electrode 22 at a predetermined temperature.

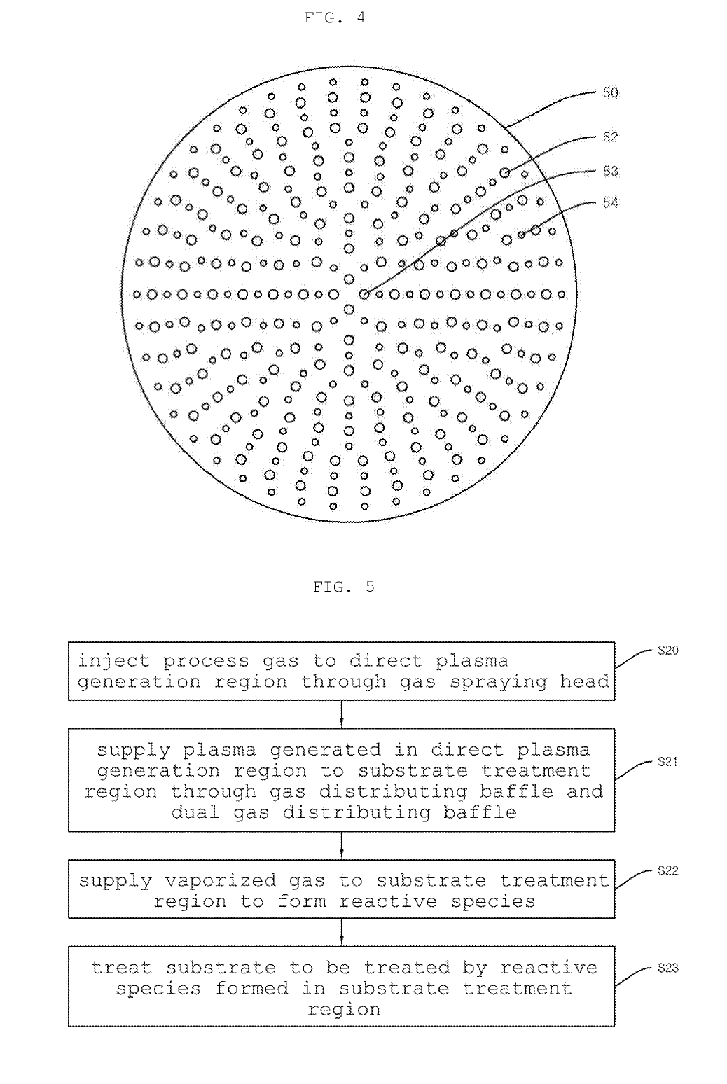

FIG. 3 is a plan view illustrating the top of the dual gas distributing baffle, and FIG. 4 is a plan view illustrating the bottom of the dual gas distributing baffle.

Referring to FIGS. 3 and 4, the through-holes 52 of the dual gas distributing baffle 50 are formed to penetrate through the dual gas distributing baffle 50. On the other hand, the center vaporized discharging outlets 53 and the edge vaporized gas discharging outlets 54 are formed in a lower portion of a vaporized gas supplying path formed in the dual gas distributing baffle 50, that is, a lower surface of the dual gas distributing baffle 50. Sizes of the through-holes 52 and the center and edge vaporized gas discharging outlets 53 and 54 may be the same as or different from each other. In addition, sizes of the center and edge vaporized gas discharging outlets 53 and 54 may also be the same as or different from each other. The sizes of the through-holes 52 and the center and edge vaporized gas discharging outlets 53 and 54 may be adjusted to adjust amounts of sprayed plasma and vaporized gas.

The center vaporized discharging outlets 53 are formed at uniform gaps in a center region of the dual gas distributing baffle 50, and the edge vaporized gas discharging outlets 54 are formed at uniform gaps in a region that is in the vicinity of the center region of the dual gas distributing baffle 50. Gaps between the respective spraying holes may be variously adjusted.

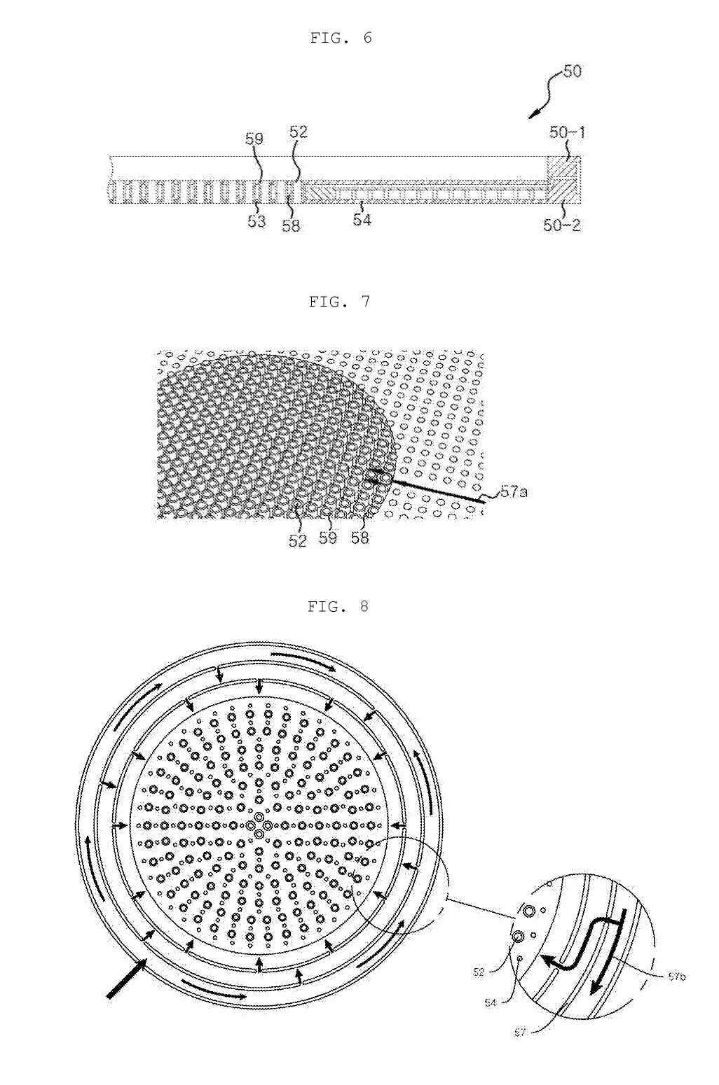

FIG. 5 is a flow chart illustrating a plasma treating method using the plasma treating apparatus according to the first exemplary embodiment.

Referring to FIG. 5, the process gas supplied from the process gas supply source 15 is supplied to the direct plasma generation region 200 through the gas spraying head 30 of the plasma treating apparatus 10 (S20). The plasma generated in the direct plasma generation region 200 is distributed to the substrate treatment region 220 through the gas distributing baffle 40 and the dual gas distributing baffle 50 (S21). The vaporized gas is supplied to a center region and an edge region of the substrate treatment region 220 through the center vaporized discharging outlets 53 and the edge vaporized gas discharging outlets 54 of the dual gas distributing baffle 50 to form the reactive species (S22). The substrate 1 to be treated is treated by the reactive species formed in the substrate treatment region 220 (S23).

FIG. 6 is a view illustrating a cross section of a dual gas distributing baffle according to a first exemplary embodiment of the present invention, FIG. 7 is a view illustrating a center buffer region of a dual gas distributing baffle, and FIG. 8 is a view illustrating an edge supply path of a dual gas distributing baffle.

Referring to FIGS. 6 to 8, the dual gas distributing baffle 50 includes a center supplying path 57a supplying the vaporized gas to a center region and an edge supplying path 57b supplying the vaporized gas to a peripheral region. Here, the edge supplying path 57b has a movement path of the vaporized gas formed by a plurality of diaphragms 57 formed along an edge of the dual gas distributing baffle 50a. In other words, the plurality of diaphragms 57 are formed along the edge of the dual gas distributing baffle 50a so as to have a gap therebetween, such that the vaporized gas moves toward the center of a plane while being rotated along the edge of the dual gas distributing baffle 50a and is sprayed to the peripheral region through the edge vaporized gas discharging outlets 54 formed in the dual gas distributing baffle 50a. The edge supplying path 57b passing between the diaphragms 57 and supplied toward the center may be formed at a width of about 5 mm.

The vaporized gas supplied through the center supplying path 57a of the dual gas distribution baffle 50 may be provided to the center buffer 58. The center buffer 58 may have a plurality of buffer fillers 59 to form a space so that the vaporized gas may be stored in the center area of the dual gas distributing baffle 50.

The center buffer 58 may be a pillar which includes a through hole 52 through which plasma passes therein or does not include through hole 52. The installation number and thickness of the buffer pillar 58 may be variously changed, and disposed structure of the buffer pillar 58 may also be variously changed depending on flow status of the vaporized gas.

A vaporized gas discharging outlet 53 to discharge the vaporized gas is included under the center buffer 58. The vaporized gas supplied through the center supplying path 57a rotates the buffer pillar 59 of the center buffer 58, is remained in the center buffer 58, and may be sprayed to a center region of the substrate treating region through the center vaporized discharging outlet 53. Since the vaporized gas may be remained in the center buffer 58 by the buffer pillar 59 for a predetermined time, the vaporized gas may be controlled in its pressure and amount to be sprayed. The center vaporized gas discharging outlet 53 and the edge vaporized gas discharging outlet 54 may be formed separately and independently.

The dual gas distribution baffle 50 may be configured of an upper plate 50-1 and a lower plate 50-2. The upper plate 50-1 and the lower plate 50-2 may commonly have a plurality of through holes 52 formed to perform plasma distribution. While the dual gas distribution baffle 50 according to the present invention may be manufactured by welding two plates as an embodiment, the dual gas distribution baffle 50 may be manufactured in a single plate, or by combining a plurality of plates.

An edge supplying path 57b is formed by a plurality of diaphragms 57 formed along an edge of the dual gas distributing baffle 50. The vaporized gas supplied to the peripheral region by the diaphragms 57 moves toward the center of a plane while being rotated along the edge of the dual gas distributing baffle 50 and is sprayed to the peripheral region through the edge vaporized gas discharging outlets 54. Amounts of the vaporized gas supplied to the center region and the peripheral region of the dual gas distributing baffle 50 may be adjusted depending on positions at which the diaphragms 57 are installed.

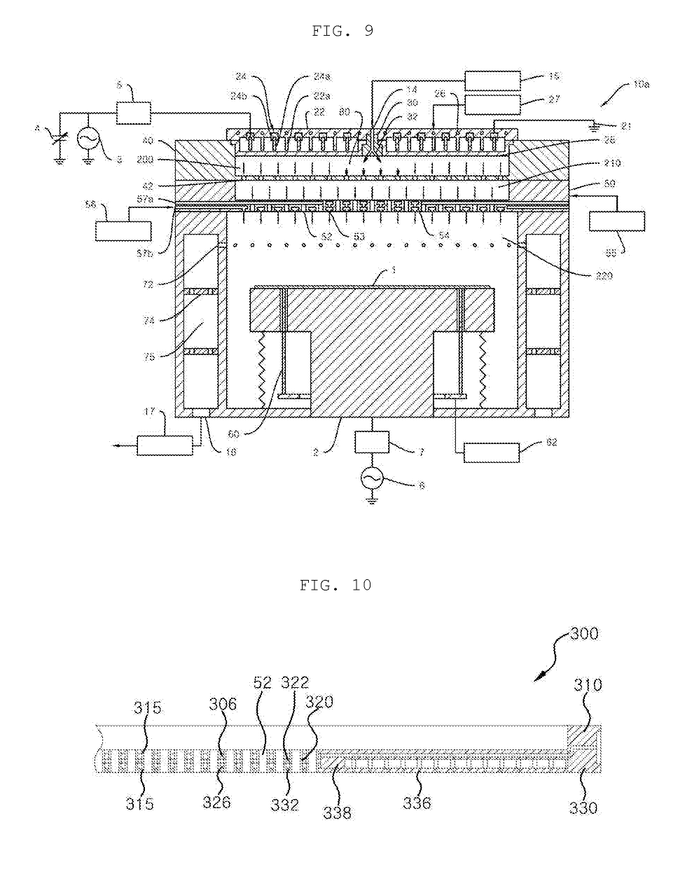

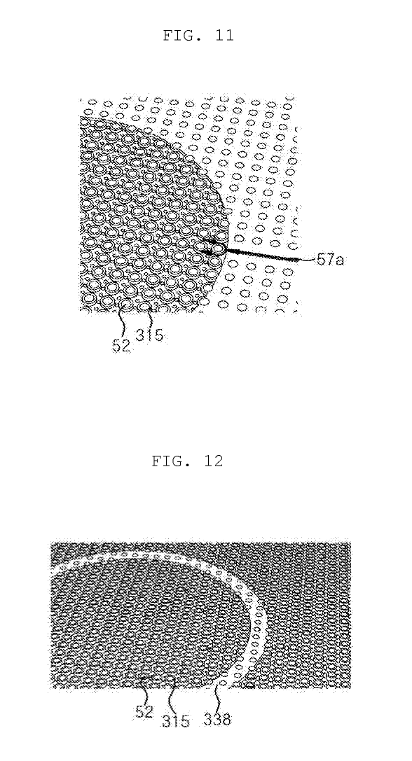

FIG. 9 is a view illustrating a plasma treating apparatus including a dual gas distribution baffle according to a second embodiment of the present invention, FIG. 10 is a view illustrating a configuration of a dual gas distribution baffle according to a second embodiment of the present invention, FIG. 11 is a view illustrating a first center buffer illustrated in FIG. 9, and FIG. 12 is a view illustrating a second center buffer illustrated in FIG. 9.

Referring to FIGS. 9 and 12, the dual gas distributing baffle 300 which is another embodiment of the present invention includes a first center buffer 306 and a second center buffer 326. The dual gas distributing baffle 300 is configured of a first plate 310 which forms an upper surface and has a plurality of through holes 302, and a third plate which forms a lower surface and has a plurality of edge vaporized gas discharging outlet 336 and a second center vaporized gas discharging outlet 332, and a second plate 320 which is included between the first plate 310 and the third plate 330 and has a plurality of first center discharging outlet 322. The first, second and third plates 310, 320 and 330 may be welded and coupled. While the dual gas distributing baffle 300 of the present invention is formed by coupling one or more plates, the dual gas distributing baffle 300 may be formed in a single plate. The center portion has a first center buffer 306 [symbol] formed between the first plate 310 and the second plate 320 has, and the center portion has a second center buffer 326 formed between the second plate 320 and the third plate 330.

The vaporized gas supplied through the center supplying path 301 is rotated and moved by a plurality of buffer pillar 315 included in the first center buffer 306. The moved vaporized gas may be sprayed into the second center buffer 326 through a plurality of first center discharging outlet 322 included in the first center buffer 326. The second center buffer 326 includes a plurality of buffer pillars 315 like the first center buffer 306. The vaporized gas sprayed into the second center buffer 326 may be sprayed into a substrate treating region through the second center vaporized gas discharging outlet 332. The vaporized gas supplied through the center supplying path 301 passes through the first and second center buffers 306 and 326 to be controlled in the flow speed so that it is uniformly sprayed into the substrate treating region. Especially, while it is not possible to control the amount and pressure of the vaporized gas supplied to the center of the substrate treating region, the amount and pressure may be controlled as the vaporized gas is supplied through first and second center buffers 306 and 326 according to the present invention. Also, it may be possible to make a uniform spray on the center region of the substrate treating region by controlling a spray time of the vaporized gas.

While a multiple center buffer is formed in a two stage according to the present invention, the number of the center buffer may be variously changed. The size of the first center vaporized gas discharging outlet 322 and the second center vaporized gas discharging outlet 332 may be identical or different each other. For example, the size of the first center vaporized gas discharging outlet 322 may be formed in 1.0Φ and the size of the second center vaporized gas discharging outlet 332 may be formed in 0.5Φ. Therefore, the vaporized gas sprayed through the first center vaporized gas discharging outlet 322 may be sprayed through the second center vaporized gas discharging outlet 332 which is downsized and the spraying speed may be controlled.

The vaporized gas supplied to the edge supplying path 57b may be sprayed into a surrounding region of the substrate treating region through an edge vaporized gas discharging outlet 336. Here, a partition wall 338 may be included in order to prevent the vaporized gas sprayed into the edge region and the center region from being mixed. The center region in which the multiple center buffer is limited to Φ100 section and the thickness of the partition wall 338 may be 6 mm. Also, when the vaporized gas is supplied to the center region like the case that the vaporized gas is supplied to the edge region, a plurality of diaphragms 57 may be installed. Also, the dual gas distributing baffle 300 may include a plurality of center supplying path 57a in order to supply the vaporized gas thereto from many directions.

The first and second center vaporized gas discharging outlets 322 and 332 may be disposed on the same line. Otherwise, they may not be disposed on the same line. The center supplying path 57a may be formed symmetrically so that it may reduce the possibility that the supplying path is closed by a pillar in the brazing process and a cleaning work may be proceeded after the processing. The center supplying path 57a may be formed in a straight line or a curved line.

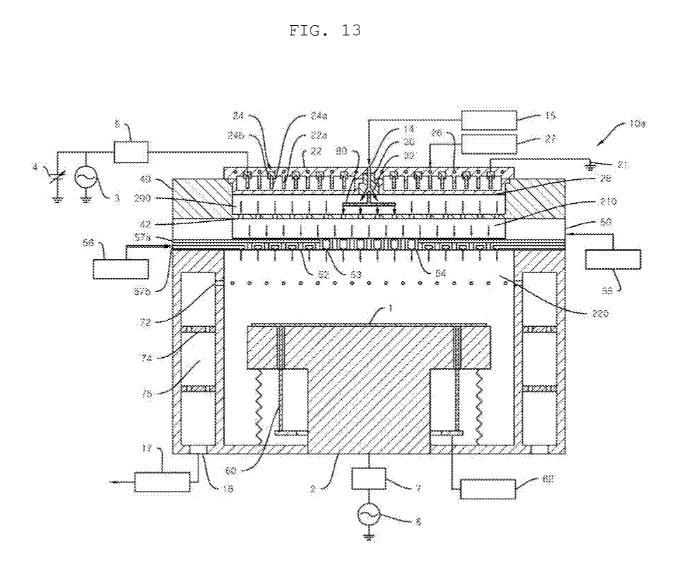

FIG. 13 is a view illustrating a plasma treating apparatus including a diffuser plate.

Referring to FIG. 13, the plasma treating apparatus 10a includes the diffuser plate 80 for uniformly diffusing the process gas. The diffuser plate 80 is made of ceramics and diffuses uniformly the process gas introduced into the chamber 12 within the direct plasma generation region 200. The diffuser plate 80 is installed in a plate shape so as to face the gas spraying head 30 and be spaced apart from the gas spraying head 30. The process gas introduced through the gas spraying head 30 is concentrated on the center of the direct plasma generation region 200, and is diffused to the edge region by the diffuser plate 80. In this case, an entire remaining time of the process gas in the direct plasma generation region 200 is increased, such that a decomposition rate rises. The process gas that is sprayed through the gas spraying head 30 and is not decomposed is intensively present on the center of the direct plasma generation region 200. Since the process gas that is sprayed through the gas spraying head 30 and is not decomposed is diffused through the diffuser plate 80 and is decomposed by the plasma, the plasma may be uniformly generated. In addition, an etch amount of silicon dioxide (SiO₂), which is an etching target, is increased. Since configurations and functions of a plasma treating apparatus according to a third exemplary embodiment except for a diffuser plate 80 are the same as those of the plasma treating apparatus illustrated in FIG. 1, a detailed description therefor will be omitted.

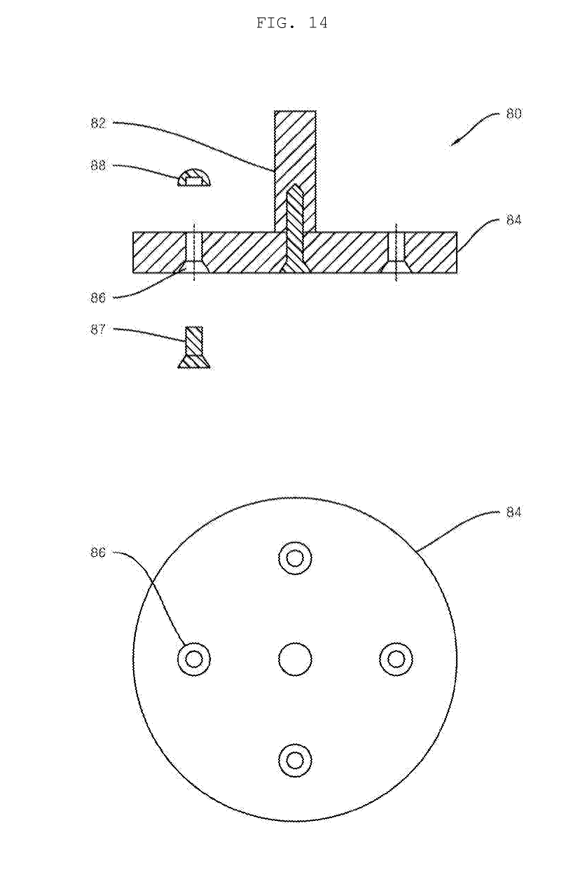

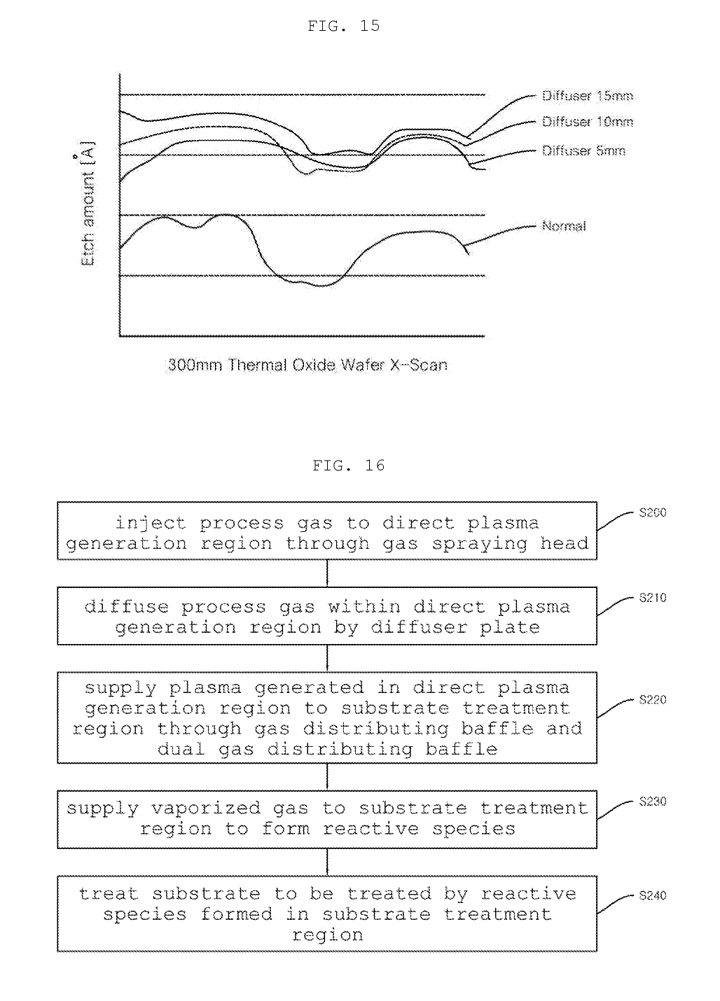

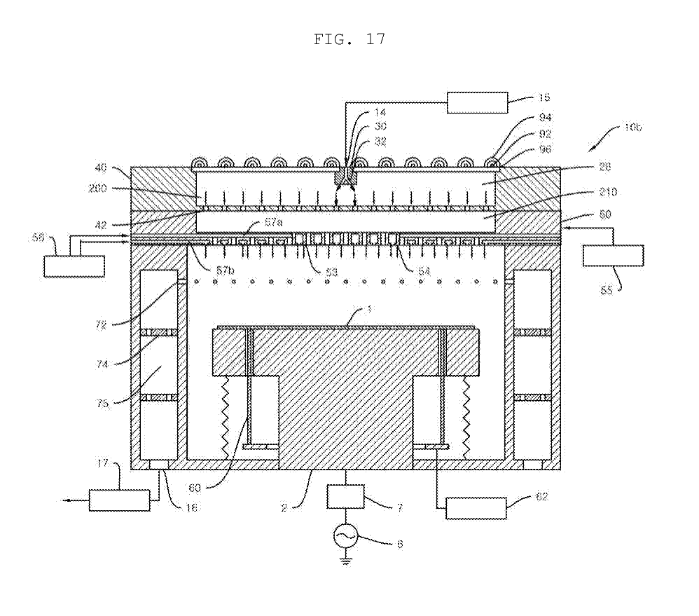

FIG. 14 is a plan view illustrating the diffuser plate.

Referring to FIG. 14, the diffuser plate 80 includes a fixing bar 82 connected to the gas spraying head 30 and a distributing plate 84 connected to the fixing bar 82 and having a plate shape. The process gas supplied from the gas spraying head 30 installed at the center of the reactor body 12 is diffused to the surrounding while colliding with the distributing plate 84. Therefore, the plasma intensively formed at the center of the direct plasma generation region 200 may be formed uniformly over the entire direct plasma generation region 200.

The distributing plate 84 may be formed of one plate in which through-holes are not formed or have a plurality of through-holes 86 formed therein. The process gas may also be distributed downwardly through the plurality of through-holes 86 while being diffused by the distributing plate 84. Stopples 87 and stopple fixing members 88 may be inserted into the through-holes 86 to stop the plurality of through-holes 86, thereby adjusting the entire number of through-holes 86. It is preferable that a diameter of the distributing plate 84 is 64Φ±10Φ, but a shape and a size of the distributing plate 84 are adjusted depending on a shape of the gas spraying head 30.

FIG. 15 is a graph illustrating a plasma uniformity depending on a gap of the diffuser plate.

Referring to FIG. 15, the plasma uniformity may be adjusted depending on a gap between the diffuser plate 80 and the gas spraying head 30. First, it may be confirmed that an etch amount and a uniformity in a condition of the case (Normal) in which the diffuser plate 80 is not included are 427 Å/min and 7.5%, respectively. As illustrated in FIG. 14, it may be appreciated that an etch amount is larger in a center region of the substrate 1 to be treated than in an edge region thereof. This means that the plasma is intensively generated in the center region.

On the other hand, it may be confirmed that an etch amount and a uniformity after the diffuser plate 80 according to the present invention is installed in a plasma treating apparatus 10a are 503 Å/min and 3.8%, respectively, in the case in which an installation gap of the diffuser plate 80 is 5 mm, are 516 Å/min and 3.4%, respectively, in the case in which an installation gap of the diffuser plate 80 is 10 mm, and are 508 Å/min and 3.3%, respectively, in the case in which an installation gap of the diffuser plate 80 is 15 mm. Therefore, the plasma uniformity may be improved through the diffuser plate 80. In addition, since a diffusion speed and distance difference of the process gas is generated depending on a change in the gap of the diffuser plate 80, the etch amount is adjusted through the change in the gap, thereby making it possible to improve the plasma uniformity.

FIG. 16 is a flow chart illustrating a plasma treating method using the plasma treating apparatus of FIG. 12.

Referring to FIG. 16, the process gas supplied from the process gas supply source 15 is supplied to the direct plasma generation region 200 through the gas spraying head 30 of the plasma treating apparatus 10a (S200). The supplied process gas is uniformly diffused within the direct plasma generation region 200 by the diffuser plate 80 (S210). The plasma generated in the direct plasma generation region 200 is supplied to the substrate treatment region through the gas distributing baffle 40 and the dual gas distributing baffle 50 (S220). The vaporized gas is sprayed to the center region and the peripheral region of the substrate treatment region, such that the plasma and the vaporized gas react to each other to form the reactive species (S230).

The substrate 1 to be treated is treated using the reactive species formed in the substrate treatment region (S240).

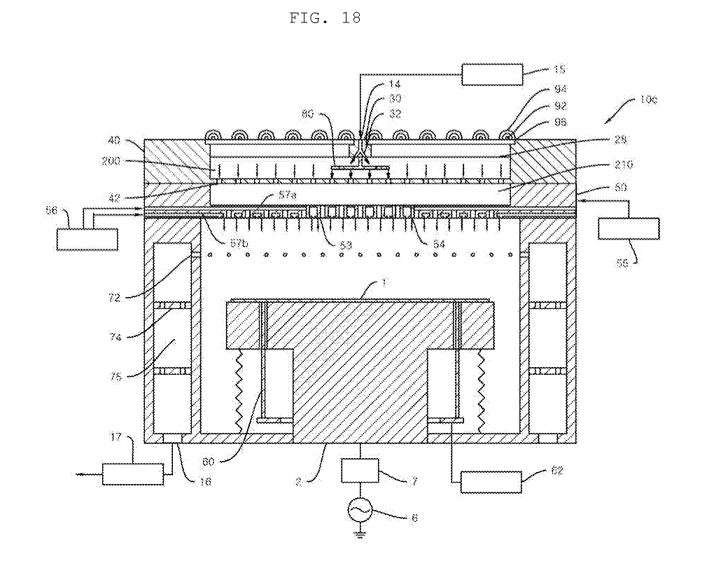

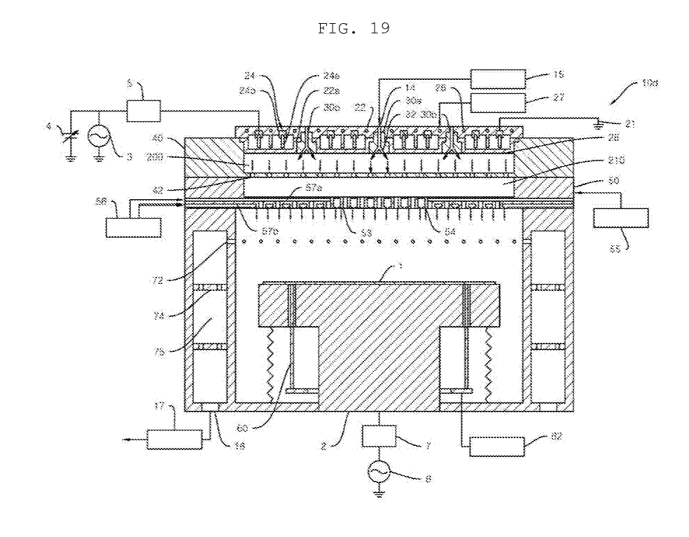

FIGS. 17 and 18 are views illustrating inductively-coupled plasma type plasma treating apparatuses.

Referring to FIGS. 17 and 18, the plasma treating apparatuses 10b and 10c include a radio frequency antenna 92 for supplying inductively-coupled plasma into the chamber 12. The radio frequency antenna 92 is wound and installed in a spiral shape on the dielectric window 96 provided on the chamber 12. The radio frequency antenna 92 is connected to the power supply 3 through the impedance matching device 5 to receive power from the power supply 3. A magnetic cover 94 is installed in a form in which it encloses an upper portion of the radio frequency antenna 92 to allow a magnetic flux to be concentrated into the chamber 12. One radio frequency antenna 92 may be installed in a spiral shape or a plurality of radio frequency antennas 92 may be installed in parallel with each other.

In addition, the plasma treating apparatus 10c further includes a diffuser plate 80 for uniformly supplying the process gas. The diffuser plate 80 is installed below the gas spraying head 30 to allow the process gas supplied into the chamber 12 to be uniformly sprayed. Since a structure and a function of the diffuser plate 80 are the same as those of the diffuser plate 80 described above, a detailed description therefor will be omitted.

FIGS. 19 and 20 are views illustrating plasma treating apparatuses having a plurality of gas inlets.

Referring to FIGS. 17 and 18, the plasma treating apparatuses 10d and 10e further include a first gas spraying head 30a for supplying the process gas to the center region of the chamber 12 and second gas spraying heads 30b for supplying the process gas to the peripheral region of the chamber 12. Amounts of the process gas supplied to the center region and the peripheral region may be adjusted through the first and second gas spraying heads 30a and 30b to adjust an entire uniformity of the plasma.

In the plasma treating apparatuses 10d and 10e, plasma sources for inducing the plasma to the center region and the peripheral region are formed to be different from each other. For example, a capacitively-coupled electrode may be installed in the center region, and a radio frequency antenna may be installed in the peripheral region. To the contrary, the radio frequency antenna may be installed in the center region, and the capacitively-coupled electrode may be installed in the peripheral region. The plasma is compositely discharged by the capacitively-coupled electrode and the radio frequency antenna.

In addition, the plasma treating apparatus 10e further includes diffuser plates 80 for uniformly supplying the process gas. The diffuser plates 80 are installed below the first and second gas spraying heads 30a and 30b, respectively, to allow the process gas supplied to the center region and the peripheral region to be uniformly sprayed. Since structures and functions of the diffuser plates 80 are the same as those of the diffuser plate 80 described above, a detailed description therefor will be omitted.

The substrate support 2 included in each of the plasma treating apparatuses 10a, 10b, 10c, 10d, and 10e having various forms described above is operated in any one of an electrostatic scheme or a vacuum scheme to fix the substrate 1 to be treated. The substrate support 2 in the present invention may be configured of a hybrid chuck that may be driven in one of the electrostatic scheme or the vacuum scheme. This hybrid chuck may be applied to all of the plasma treating apparatuses 10a, 10b, 10c, 10d, and 10e described above.

Next, a configuration and an operation method of the hybrid chuck will be described.

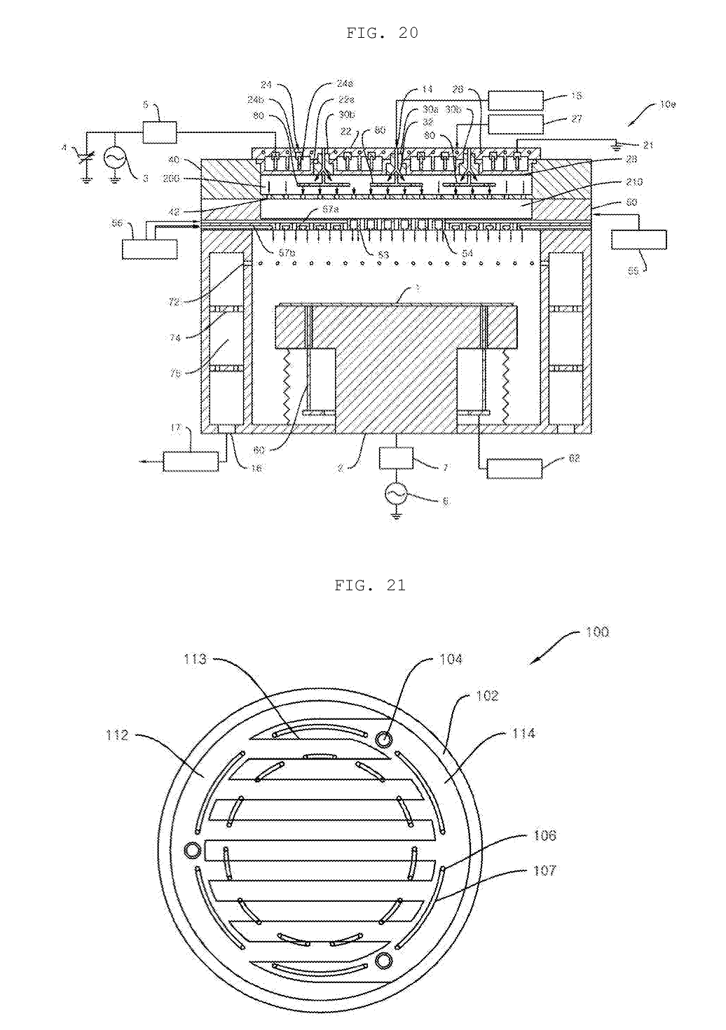

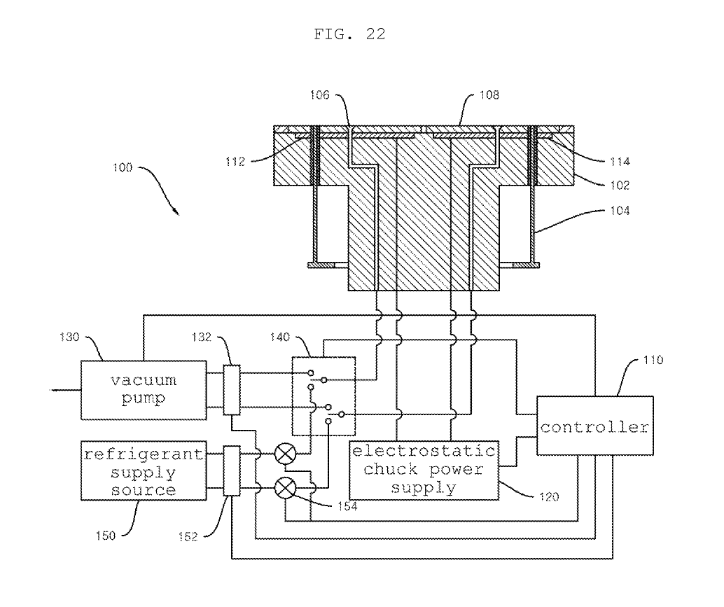

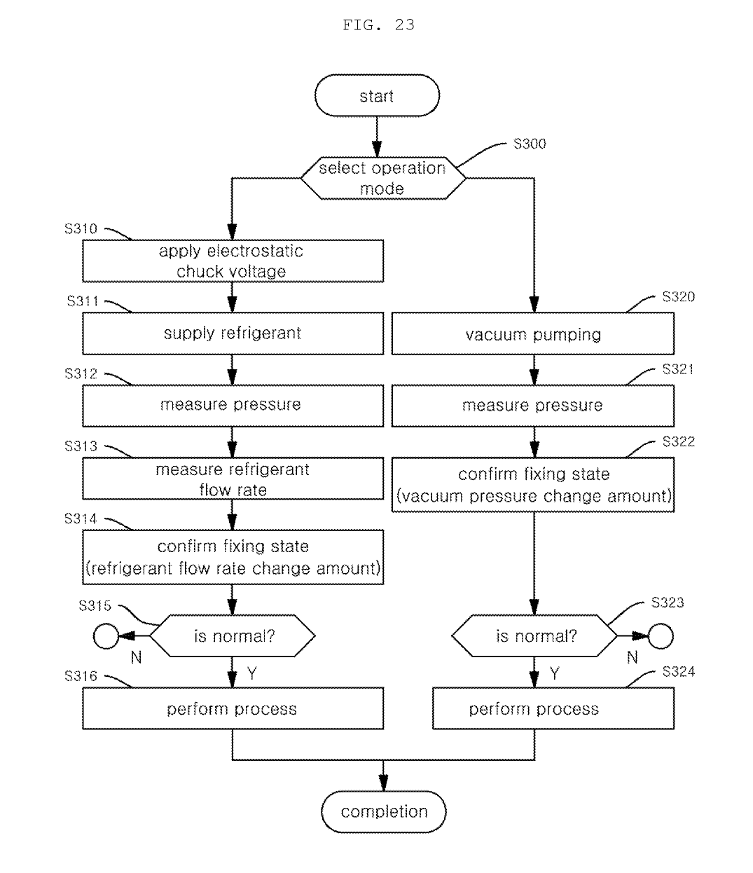

FIG. 21 is a view illustrating a plane of a hybrid chuck according to an exemplary embodiment of the present invention, and FIG. 22 is a view illustrating a cross section of the hybrid chuck of FIG. 21.

Referring to FIGS. 21 and 22, the hybrid chuck according to the present invention will be called a substrate support 100 for supporting the substrate 1 to be treated. The substrate support 100 includes a body part 102, first and second electrode parts 112 and 114, and hybrid lines 106.

The body part 102 is a base part on which the substrate 1 to be treated is seated and is provided in a plasma chamber. A shape of the body part 102 may be modified into various shapes such as a circular shape, a rectangular shape, and the like, depending on a shape of the substrate 1 to be treated. The body part 102 is provided with a lift pin 104 for raising or lowering the substrate 1 to be treated while supporting the substrate 1 to be treated. The substrate 1 to be treated may be, for example, a silicon wafer substrate for manufacturing a semiconductor apparatus or a glass substrate for manufacturing a liquid crystal display, a plasma display, or the like.

The first and second electrode parts 112 and 114 are formed on an upper surface of the body part 102 on which the substrate 1 to be treated is seated. A dielectric layer 108 is formed on upper surfaces of the first and second electrode parts 112 and 114, and the substrate 1 to be treated is seated on the dielectric layer 108. The dielectric layer 108 may be formed in one plate shape or be formed in the same shape as those of the first and second electrode parts 112 and 114. The first and second electrode parts 112 and 114 are formed in a zigzag shape and are installed as if they are fitted into each other. The above-mentioned shapes of the electrode parts increase a contact surface between the electrode parts and the substrate to be treated, thereby making it possible to maximize generation of electrostatic force. The shapes of the electrode parts in the present invention are only an example, and may be variously modified. In the case in which the first and second electrode parts 112 and 114 are connected to an electrostatic chuck power supply 120 to drive the substrate support 100 in the electrostatic scheme, they receive a voltage for generating the electrostatic force.

An insulating part 113 for electrically insulating the first and second electrode parts 112 and 114 from each other is provided between the first and second electrode parts 112 and 114. The hybrid chuck according to the present invention may include one electrode on the body part 102 in a unipolar (or monopolar) scheme to generate the electrostatic force. Preferably, since a separate electric field is not required when the substrate is fixed, the hybrid chuck may include two or more electrodes in a bipolar scheme to generate the electrostatic force. In the present invention, the first and second electrode parts 112 and 114 in the bipolar scheme are disclosed and described.

One or more of the hybrid lines 106 are formed to penetrate through the body part 102. One or more hybrid line 106 is connected to a vacuum pump 130, and in the case in which the substrate support 100 is driven in the vacuum scheme, air is sucked through the hybrid line 106 to fix the substrate 1 to be treated seated on the upper surface of the body part 102.

The hybrid line 106 may be connected to a refrigerant supply source 150 to thereby be used as a cooling channel for cooling the substrate 1 to be treated. In other words, the hybrid line 106 fixes the substrate 1 to be treated by sucking the air in the case in which the substrate support 100 is driven in the vacuum scheme and cools the substrate 1 to be treated by receiving a refrigerant in the case in which the substrate support 100 is driven in the electrostatic scheme.

Two or more hybrid lines 106 are connected to each other to form a refrigerant circulation path 107. The refrigerant circulation path 107 is formed in a concentric circle shape on the dielectric layer 108 positioned on the upper surface of the body part 102. The refrigerant circulation path 107 is uniformly distributed over the entire upper surface of the body part 102. In the refrigerant circulation path 107, one hybrid line 106 is used as a refrigerant supplying path, and the other hybrid line 106 is used as a refrigerant discharging path. The refrigerant is supplied from the refrigerant supply source 150 through one hybrid line 106, adjusts a temperature of the substrate 1 to be treated while being circulated along the refrigerant circulation path 107, and is then discharged again through the other hybrid line 106. Here, flow rate adjusting valves 154 for adjusting a flow rate of the refrigerant are connected to the hybrid lines 106, respectively. In the substrate support 100 driven in the vacuum scheme, helium (He) gas may be supplied as the refrigerant.

In the case in which the substrate support 100 is driven in the vacuum scheme, the first and second electrode parts 112 and 114 are driven to fix the substrate 1 to be treated by electrical force. In the vacuum scheme, there is no limitation in an atmosphere in a chamber in which the substrate support 100 is installed, and the helium gas adjusts a temperature of the substrate 1 to be treated while being circulated to a rear surface of the substrate 1 to be treated through the refrigerant circulation path 107 and the hybrid line 106, thereby improving a uniformity of the temperature.

The hybrid line 106 is connected to the vacuum pump 130 or the refrigerant supply source 150 through a switching valve 140. When the switching valve 140 receives a signal for driving in the vacuum scheme from a controller 110, it connects the hybrid line 106 and the vacuum pump 130 to each other. In addition, when the switching valve 140 receives a signal for driving in the electrostatic scheme from the controller 110, it connects the hybrid line 106 and the refrigerant supply source 150 to each other. Here, the controller 110 transmits a driving signal to the electrostatic chuck power supply 120.

In order to confirm a state in which the substrate 1 to be treated is fixed to the substrate support 100, a pressure measuring sensor part 132 is provided between the hybrid line 106 and the vacuum pump 130. The pressure measuring sensor part 132 measures a vacuum pressure change amount of the hybrid line 106 to confirm the state in which the substrate 1 to be treated is fixed. In addition, in order to confirm the state in which the substrate 1 to be treated is fixed to the substrate support 100, a flow rate measuring sensor part 152 is provided between the hybrid line 106 and the refrigerant supply source 150. The flow rate measuring sensor part 152 measures a refrigerant flow rate change amount of the hybrid line 106 and the refrigerant circulation path 107 to confirm the state in which the substrate 1 to be treated is fixed.

The substrate support 100 according to the related art was mainly made of ceramic. However, the substrate support 100 in the present invention is made of polyimide. The ceramic has advantages such as high durability, high thermal conductivity, and excellent adsorptive power. However, the ceramic has disadvantages such as a high cost, a difficult manufacturing process, and absorption of moisture due to porosity. On the other hand, the polyimide is cheap and has excellent heat resistance, such that a change in characteristics from a low temperature to a high temperature is small. In addition, the polyimide has advantages such as a high breakdown voltage and a short discharging time. In addition, the polyimide is not affected by moisture, such that it may be utilized in a range wider than that of the ceramic.

FIG. 23 is a flow chart of an operation method of the hybrid chuck.

Referring to FIG. 23, when the substrate 1 to be treated is introduced into a chamber in order to perform a process, a user or the controller 110 selects whether to drive the substrate support 100 in the electrostatic scheme or in the vacuum scheme (S300). The scheme may be manually selected by the user or be systematically selected depending on an atmosphere in the chamber or a state of the substrate support 100 by the controller 110.

In the case in which it is selected to operate the substrate support in the electrostatic scheme, an electrostatic chuck voltage is applied from the electrostatic chuck power supply 120 to the first and second electrode parts 112 and 114 (S310). The refrigerant supplied from the refrigerant supply source 150 is circulated along the hybrid line 106 and the refrigerant circulation path 107 (S311). A pressure of the circulated refrigerant is measured using a pressure measuring apparatus (not illustrated) (S312), and a flow rate of the refrigerant is measured though the flow rate measuring sensor part 152 and is transmitted to the controller (S313). The controller 110 confirms the state in which the substrate 1 to be treated is fixed through the measured flow rate change amount of the refrigerant. For example, the controller 110 may compare data on a flow rate change in a state in which the substrate 1 to be treated is normally fixed and a state in which the substrate 1 to be treated is abnormally fixed with the measured flow rate change amount to confirm the state in which the substrate 1 to be treated is fixed (S314). When it is decided that the refrigerant flow rate change amount is normal, a process for the substrate 1 to be treated is performed (S316). However, when it is decided that the substrate 1 to be treated is not normally fixed through the refrigerant flow rate change amount, the substrate 1 to be treated is again seated on the substrate support 100, and the above-mentioned process may be repeated. Alternatively, it is decided that driving in the electrostatic scheme is not smooth, such that an operation scheme is switched to the vacuum scheme, and the substrate 1 to be treated may be fixed to the substrate support 100 (S315). The switching of the operation scheme as described above may be manually made by the user or be automatically made by decision of the controller 110.

In the case in which it is selected to operate the substrate support in the vacuum scheme, the vacuum pump 130 is driven to suck air through the hybrid line 106 (S320). A vacuum pressure of the hybrid line 106 is measured through the pressure measuring sensor part 132 and is then transmitted to the controller (S321). The controller 110 confirms the state in which the substrate 1 to be treated is fixed through the measured vacuum pressure change amount. For example, the controller 110 may compare data on a pressure change in a state in which the substrate 1 to be treated is normally fixed and a state in which the substrate 1 to be treated is abnormally fixed with the measured pressure change amount to confirm the state in which the substrate 1 to be treated is fixed (S322). When it is decided that the vacuum pressure change amount is normal, a process for the substrate 1 to be treated is performed (S324). However, when it is decided that the substrate 1 to be treated is not normally fixed through the vacuum pressure change amount, the substrate 1 to be treated is again seated on the substrate support 100, and the above-mentioned process may be repeated. Alternatively, it is decided that driving in the vacuum scheme is not smooth, such that an operation scheme is switched to the electrostatic scheme, and the substrate 1 to be treated may be fixed (S323). The switching of the operation scheme as described above may be manually made by the user or be automatically made by decision of the controller 110.

Therefore, when the hybrid chuck according to the present invention is used, a substrate fixing scheme may be selected depending on a process atmosphere and an environment. In addition, in the case in which one scheme may not be used, another scheme may be selected to fix the substrate. Therefore, a substrate treating process needs not to be stopped nor the chuck needs to be replaced at the time of generation of a fault, such that productivity is increased and a repairing cost and a production cost are decreased.

With the plasma treating apparatus for vapor phase etching and cleaning according to the present invention, the reactive species are formed to treat the substrate to be treated, thereby making it possible to treat the substrate to be treated without the plasma damage. In addition, at the time of cleaning the substrate to be treated, a byproduct is not generated, and selectivity is high. Further, since the vaporized gas for vapor phase cleaning is provided to the center and edge regions, an amount of the sprayed vaporized gas is adjusted, thereby making it possible to entirely uniformly generate the reactive species to uniformly treat the surface of the substrate to be treated. A temperature of the vaporized gas may be adjusted using the heat wire provided in the gas distributing baffle spraying the vaporized gas. In addition, since the plasma damage is not generated, the substrate to be treated may be treated in a fine pattern forming process. Further, since the process gas is uniformly diffused into the chamber through the diffuser plate, the plasma is uniformly generated. Large-region plasma may be uniformly generated, such that a large substrate as well as a small substrate may be uniformly treated. In addition, installation gaps between the diffuser plates are adjusted, thereby making it possible to adjust a diffusion degree of the process gas. Further, a remaining time of the process gas is increased to raise a gas decomposition rate, such that an etch amount is increased. Further, since the hybrid chuck may be further provided and be driven in one of the electrostatic scheme and the vacuum scheme in order to support the substrate depending on a process of treating the substrate, a substrate fixing scheme may be selected depending on a process atmosphere and an environment. Further, in the case in which one scheme may not be used, another scheme may be selected to fix the substrate. Therefore, the substrate treating process needs not to be stopped nor the chuck needs to be replaced at the time of generation of a fault. Further, productivity is increased and a repairing cost and a production cost are decreased.

An exemplary embodiment of the plasma treating apparatus for vapor phase etching and cleaning according to the present invention described above is only an example, and it may be appreciated by those skilled in the art to which the present invention pertains that various modifications and equivalent other exemplary embodiments may be made from the exemplary embodiment.

Therefore, it may be understood well that the present invention is not limited to only a form mentioned in the above detailed description. Accordingly, an actual technical protection scope of the present invention is to be defined by the following claims. In addition, it is to be understood that the present invention includes all modifications, equivalents, and substitutes that are in the spirit and scope of the present invention.

What is claimed is:

1. A plasma treating apparatus having a dual gas distribution baffle for a uniform gas distribution, comprising:
a chamber configured to treat a substrate to be treated;
a direct plasma generation region in the chamber into which process gas is introduced to directly induce plasma;
a plasma inducing assembly configured to induce the plasma to the direct plasma generation region;
a substrate treatment region in the chamber in which the plasma introduced from the direct plasma generation region and vaporized gas introduced from the outside of the chamber are mixed with each other to form reactive species and the substrate to be treated is treated by the reactive species;
a dual gas distributing baffle included between the direct plasma generation region and the substrate treatment region to provide the plasma to the substrate treatment region and distribute the vaporized gas to a center region and a peripheral region of the substrate treatment region;
a plurality of through-holes formed through the dual gas distributing baffle so as to provide plasma generated in the direct plasma generation region to the substrate treating region;
a center buffer region configured to be include in the dual gas distribution baffle and to store the vaporized gas supplied through the vaporized gas supplying path;
one or more center vaporized gas discharging outlet configured to be included in the dual gas distribution baffle in order to spray the vaporized gas supplied to the center buffer region into the center region of the substrate treatment region; and
one or more edge vaporized gas discharging outlet configured to spray the vaporized gas supplied through the vaporized gas supplying path formed in the dual gas distributing baffle into the peripheral region of the substrate treatment region.

2. The plasma treating apparatus of claim 1, wherein the plasma inducing assembly is a capacitively-coupled electrode assembly including a plurality of capacitively-coupled electrodes or a radio frequency antenna.

3. The plasma treating apparatus of claim 2, wherein the plasma inducing assembly includes:
a center plasma inducing assembly configured to induce the plasma to a center region of the direct plasma generation region; and
an edge plasma inducing assembly configured to induce the plasma to a peripheral region of the direct plasma generation region.

4. The plasma treating apparatus of claim 1, wherein the dual gas distributing baffle includes a heat wire.

5. The plasma treating apparatus of claim 1, wherein the vaporized gas is vaporized H₂O.

6. The plasma treating apparatus of claim 1, wherein the plasma apparatus includes one or mere gas inlets to supply the process gas into the chamber.

7. The plasma treating apparatus of claim 6, wherein the plasma treating apparatus includes a diffuser plate installed to face the gas inlet through which the process gas is introduced to diffuse the process gas in the direct plasma generation region.

8. The plasma treating apparatus of claim 1, wherein the center buffer region includes one or more buffer pillars in the center buffer region so that the vaporized gas supplied to the center buffer region is rotated and moved.

9. The plasma treating apparatus of claim 1, wherein the dual gas distribution baffle includes:
a first center buffer region configured to store vaporized gas supplied through the vaporized gas supplying path;
a first center vaporized gas discharging outlet configured to discharge the vaporized gas from the first center buffer region and to be formed therethrough;
a second center buffer region configured to store the vaporized gas supplied through the first center vaporized gas discharging outlet; and
a second center vaporized gas discharging outlet configured to spray the vaporized gas from the second center buffer region to the substrate treating region.

10. The plasma treating apparatus of claim 9, wherein the first and second center buffer regions include one or more buffer pillars through which the vaporized gas is rotated and moved.
